(19) United States
(12) Patent Application Publication
(10) Pub. No.: US 2026/0068191 A1
(43) Pub. Date: Mar. 5, 2026

(54) SEMICONDUCTOR DEVICE

(71) Applicant: Kioxia Corporation, Tokyo (JP)

(72) Inventors: Tsuyoshi ETOU, Yokohama (JP); Tomohito KAWANO, Yokohama (JP); Akiyoshi ITOU, Shinagawa (JP); Tsuneo HAMAI, Fujisawa (JP); Toshikazu WATANABE, Chigasaki (JP); Sachie FUKUDA, Ota (JP); Haruka SHIBAYAMA, Kamakura (JP); Kazuto SHITARA, Kamakura (JP); Yoshihiko OGASAWARA, Yokohama (JP); Takumi ONO, Kamakura (JP)

(73) Assignee: Kioxia Corporation, Tokyo (JP)

(21) Appl. No.: 18/978,706

(22) Filed: Dec. 12, 2024

(30) Foreign Application Priority Data
Aug. 30, 2024 (JP) 2024-148206

(51) Int. Cl. H10D 1/47; H01L 21/762; H01L 23/00; H01L 25/16; H10B 80/00; H10D 89/10

(52) U.S. Cl. CPC H10D 1/47; H10B 80/00; H10D 89/10

(57) ABSTRACT

A semiconductor device includes a plurality of first resistor elements, an insulating layer and a plurality of second resistor elements. The plurality of first resistor elements are disposed at a side of a main surface of a semiconductor substrate, extending in a first direction parallel to the main surface of the semiconductor substrate, arranged in a second direction parallel to the main surface of the semiconductor substrate and intersecting with the first direction. The insulating layer is disposed at the side of the main surface of the semiconductor substrate between the respective plurality of first resistor elements and having an electrode installation surface in contact with the electrode layer. The plurality of second resistor elements are disposed on the electrode installation surface of the insulating layer between the plurality of first resistor elements, extending in the first direction, arranged in the second direction.

### CROSS-REFERENCE TO RELATED APPLICATIONS

This application is based upon and claims the benefit of Japanese Patent Application No. 2024-148206, filed on Aug. 30, 2024, the entire contents of which are incorporated herein by reference.

### BACKGROUND

### Field

Embodiments described herein relate generally to a semiconductor device.

### Description of the Related Art

There has been known a semiconductor device having a first resistor element formed of a diffusion layer and a second resistor element formed of a conductive layer provided on its substrate.

### BRIEF DESCRIPTION OF THE DRAWINGS

FIG. 1 is a schematic block diagram illustrating a configuration of a memory die MD according to a first embodiment;

FIG. 2 is a schematic circuit diagram illustrating a configuration of a part of the memory die MD;

FIG. 3 is a schematic exploded perspective view illustrating an exemplary configuration of a memory die MD;

FIG. 4 is a schematic bottom view illustrating an exemplary configuration of a chip C_{M};

FIG. 5 is a schematic cross-sectional view illustrating a configuration of a part of the memory die MD;

FIG. 6 is a schematic cross-sectional view illustrating a configuration of a part of the memory die MD;

FIG. 7 is a schematic plan view illustrating an exemplary configuration of a chip C_{P};

FIG. 8 is a schematic plan view illustrating an enlarged circuit region A in a peripheral circuit region R_{PC} illustrated in FIG. 7;

FIG. 9 is a plan view illustrating diffusion resistors R_{DIFF} and GC resistors R_{GC} according to a first embodiment;

FIG. 10 is a cross-sectional view illustrating the diffusion resistors R_{DIFF} and the GC resistors R_{GC} according to the first embodiment;

FIG. 11 is a cross-sectional view that illustrates a modification of the first embodiment and corresponds to FIG. 10;

FIG. 12 is a cross-sectional view for describing a method for manufacturing the diffusion resistors R_{DIFF} and the GC resistors R_{GC} according to the embodiment;

FIG. 13 is a cross-sectional view for describing the method for manufacturing the diffusion resistors R_{DIFF} and the GC resistors R_{GC} according to the embodiment;

FIG. 14 is a cross-sectional view for describing the method for manufacturing the diffusion resistors R_{DIFF} and the GC resistors R_{GC} according to the embodiment;

FIG. 15 is a cross-sectional view for describing the method for manufacturing the diffusion resistors R_{DIFF} and the GC resistors R_{GC} according to the embodiment;

FIG. 16 is a cross-sectional view for describing the method for manufacturing the diffusion resistors R_{DIFF} and the GC resistors R_{GC} according to the embodiment;

FIG. 17 is a cross-sectional view for describing the method for manufacturing the diffusion resistors R_{DIFF} and the GC resistors R_{GC} according to the embodiment;

FIG. 18 is a plan view illustrating diffusion resistors R_{DIFF} and GC resistors R_{GC} according to a second embodiment;

FIG. 19 is a cross-sectional view illustrating the diffusion resistors R_{DIFF} and the GC resistors R_{GC} according to the second embodiment;

FIG. 20 is a plan view illustrating diffusion resistors R_{DIFF} and GC resistors R_{GC} according to a third embodiment;

FIG. 21 is a cross-sectional view illustrating the diffusion resistors R_{DIFF} and the GC resistors R_{GC} according to the third embodiment;

FIG. 22 is a plan view illustrating diffusion resistors R_{DIFF} and GC resistors R_{GC} according to a fourth embodiment;

FIG. 23 is a cross-sectional view illustrating the diffusion resistors R_{DIFF} and the GC resistors R_{GC} according to the fourth embodiment;

FIG. 24 is a plan view illustrating diffusion resistors R_{DIFF} and GC resistors R_{GC} according to a fifth embodiment; and

FIG. 25 is a plan view illustrating diffusion resistors R_{DIFF} and GC resistors R_{GC} according to a sixth embodiment.

### DETAILED DESCRIPTION

A semiconductor device according to one embodiment comprises: a semiconductor substrate having a main surface which includes a first direction and a second direction intersecting with the first direction; an electrode layer disposed at a side to the main surface. A plurality of first resistor elements disposed at a side of the main surface of the semiconductor substrate, extending in the first direction, arranged in the second direction, and formed of a plurality of diffusion layers having first connecting terminal portions at end portion sides in the first direction; and an insulating layer disposed at the side of the main surface of the semiconductor substrate between the respective plurality of first resistor elements and having an electrode installation surface in contact with the electrode layer. The electrode layer includes a plurality of second resistor elements disposed on the electrode installation surface of the insulating layer between the plurality of first resistor elements, extending in the first direction, arranged in the second direction, and formed of a plurality of conductive layers having second connecting terminal portions at end portion sides in the first direction.

Next, the semiconductor devices according to embodiments are described in detail with reference to the drawings. The following embodiments describe “semiconductor memory devices” as examples of semiconductor devices. However, the following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when referring to a “semiconductor memory device”, it may mean a memory die and may mean a memory system including a controller die, such as a memory chip, a memory card, and a Solid State Drive (SSD). Further, it may mean a configuration including a host computer, such as a smartphone, a tablet terminal, and a personal computer.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, when it is referred that the first configuration “is connected between” the second configuration and a third configuration, it may mean that the first configuration, the second configuration, and the third configuration are connected in series and the second configuration is connected to the third configuration via the first configuration.

In this specification, when it is referred that a circuit or the like “electrically conducts” two wirings or the like, it may mean, for example, that this circuit or the like includes a transistor or the like, this transistor or the like is disposed in a current path between the two wirings, and this transistor or the like is turned ON.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction along a predetermined plane may be referred to as a first direction, a direction along this predetermined plane and intersecting with the first direction may be referred to as a second direction, and a direction intersecting with this predetermined plane may be referred to as a third direction. These first direction, second direction, and third direction may each correspond to any of the X-direction, the Y-direction, and the Z-direction and need not correspond to these directions.

Expressions such as “above” and “below” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion at the substrate side of this configuration. An upper surface and an upper end of a certain configuration mean a surface and an end portion at a side opposite to the substrate of this configuration. A surface intersecting with the X-direction or the Y-direction is referred to as a side surface and the like.

In this specification, when referring to a “width”, a “length”, a “thickness”, or the like of a configuration, a member, or the like in a predetermined direction, this may mean a width, a length, a thickness, or the like in a cross-sectional surface or the like observed with a Scanning Electron Microscopy (SEM), a Transmission Electron Microscopy (TEM), or the like.

In this specification, when referring to a “wiring”, this may include a wiring, a via-contact electrode, a connecting portion for connecting a wiring to a via-contact electrode, a bonding electrode, or the like.

### First Embodiment

### [Circuit Configuration of Memory Die MD]

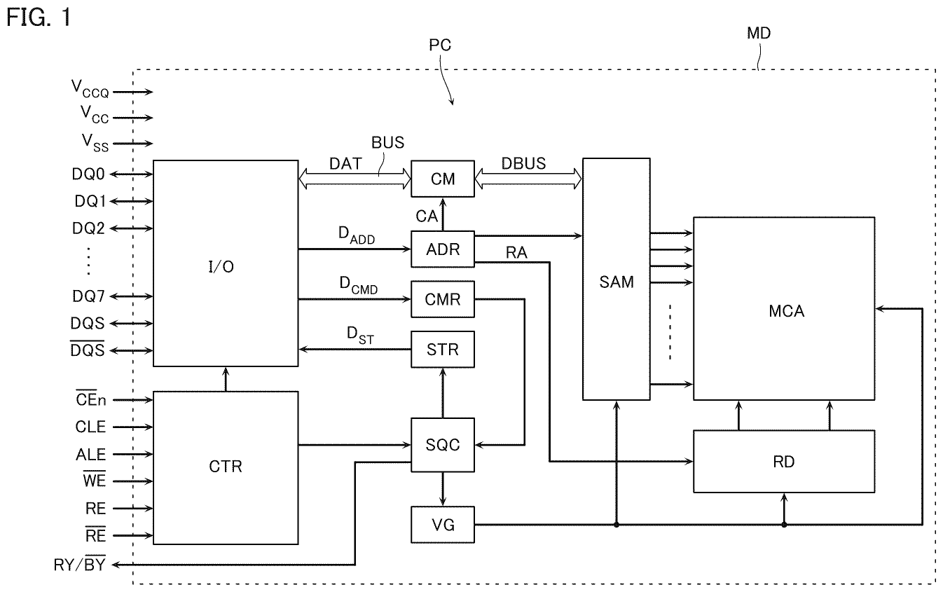

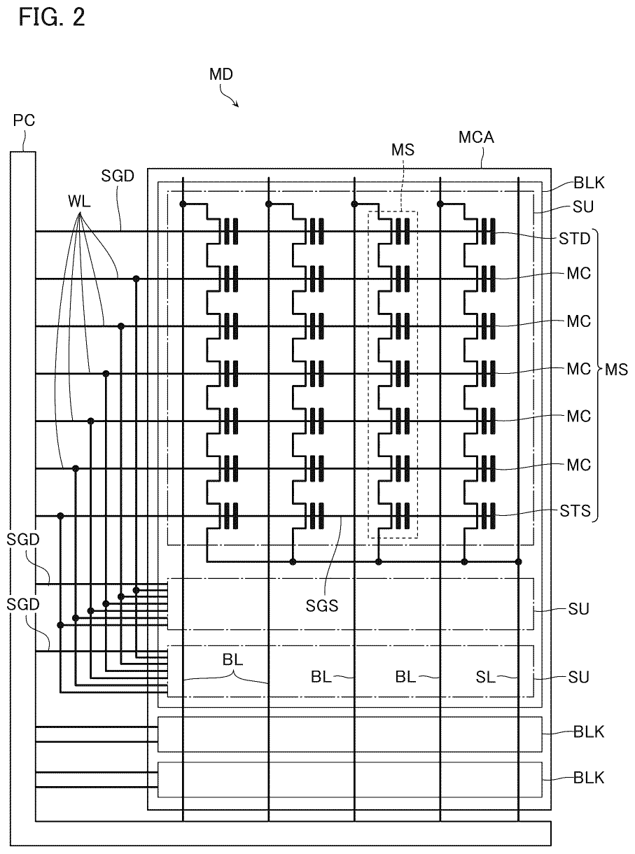

FIG. 1 is a schematic block diagram illustrating a configuration of a memory die MD according to the first embodiment. FIG. 2 is a schematic circuit diagram illustrating a configuration of a part of the memory die MD.

As illustrated in FIG. 1, the memory die MD includes a memory cell array MCA and a peripheral circuit PC. The peripheral circuit PC includes a voltage generation circuit VG, a row decoder RD, a sense amplifier module SAM, and a sequencer SQC. The peripheral circuit PC includes a cache memory CM, an address register ADR, a command register CMR, and a status register STR. The peripheral circuit PC includes an input/output control circuit I/O and a logic circuit CTR.

### [Circuit Configuration of Memory Cell Array MCA]

The memory cell array MCA includes a plurality of memory blocks BLK as illustrated in FIG. 2. These plurality of memory blocks BLK each include a plurality of string units SU. These plurality of string units SU each include a plurality of memory strings MS. These plurality of memory strings MS have one ends each connected to the peripheral circuit PC via bit lines BL. These plurality of memory strings MS have the other ends each connected to the peripheral circuit PC via a common source line SL.

The memory string MS includes a drain-side select transistor STD, a plurality of memory cells MC (memory transistor), and a source-side select transistor STS. The drain-side select transistor STD, the plurality of memory cells MC, and the source-side select transistor STS are connected in series between the bit line BL and the source line SL. Hereinafter, the drain-side select transistor STD and the source-side select transistor STS may be simply referred to as select transistors (STD, STS).

The memory cell MC is a field-effect type transistor. The memory cell MC includes a semiconductor layer, a gate insulating film, and a gate electrode. The semiconductor layer functions as channel regions. The gate insulating film includes an electric charge accumulating film. The memory cell MC has a threshold voltage that changes according to an electric charge amount in the electric charge accumulating film. The memory cell MC stores data of one bit or a plurality of bits. The gate electrodes of the plurality of memory cells MC corresponding to one memory string MS are connected to respective word lines WL. These respective word lines WL are connected in common to all the memory strings MS in one memory block BLK.

The select transistors (STD, STS) are field-effect type transistors. The select transistors (STD, STS) include a semiconductor layer, a gate insulating film, and a gate electrode. The semiconductor layer functions as channel regions. The gate insulating film may include an electric charge accumulating layer. Select gate lines (SGD, SGS) are connected to the respective gate electrodes of the select transistors (STD, STS). One drain-side select gate line SGD is connected in common to all the memory strings MS in one string unit SU. One source-side select gate line SGS is connected in common to all the memory strings MS in one memory block BLK. The drain-side select gate line SGD and the source-side select gate line SGS may each be referred to as a select gate line SG.

### [Structure of Memory Die MD]

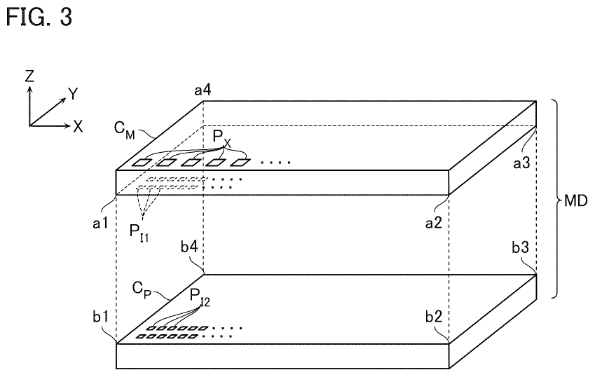

FIG. 3 is a schematic exploded perspective view illustrating an exemplary configuration of a semiconductor memory device according to the first embodiment. As illustrated in FIG. 3, the memory die MD includes a chip C_{M} at a memory cell array MCA side and a chip C_{P} at a peripheral circuit PC side.

On an upper surface of the chip C_{M}, a plurality of external pad electrodes P_{X} connectable to bonding wires (not illustrated) are disposed. Additionally, a plurality of bonding electrodes P_{I1} are disposed on a lower surface of the chip C_{M}. A plurality of bonding electrodes P_{I2} are disposed on an upper surface of the chip C_{P}. Hereinafter, regarding the chip C_{M}, a surface on which the plurality of bonding electrodes P_{I1} are disposed is referred to as a front surface, and a surface on which the plurality of external pad electrodes P_{X} are disposed is referred to as a back surface. Regarding the chip C_{P}, a surface on which the plurality of bonding electrodes P_{I2} are disposed is referred to as a front surface, and a surface at a side opposite to the front surface is referred to as a back surface. In the illustrated example, the front surface of the chip C_{P} is disposed above the back surface of the chip C_{P}, and the back surface of the chip C_{M} is disposed above the front surface of the chip C_{M}.

The chip C_{M} and the chip C_{P} are placed such that the front surface of the chip C_{M} is opposed to the front surface of the chip C_{P}. The respective plurality of bonding electrodes P_{I1} are disposed corresponding to the plurality of bonding electrodes P_{I2} and are placed at positions where the plurality of bonding electrodes P_{I1} can be bonded to the plurality of bonding electrodes P_{I2}. The bonding electrodes P_{I1} and the bonding electrodes P_{I2} function as bonding electrodes for bonding the chip C_{M} and the chip C_{P} and electrically conducting the chip C_{M} and the chip C_{P}.

Note that in the example of FIG. 3, corner portions a1, a2, a3, a4 of the chip C_{M} correspond to corner portions b1, b2, b3, b4 of the chip C_{P}, respectively.

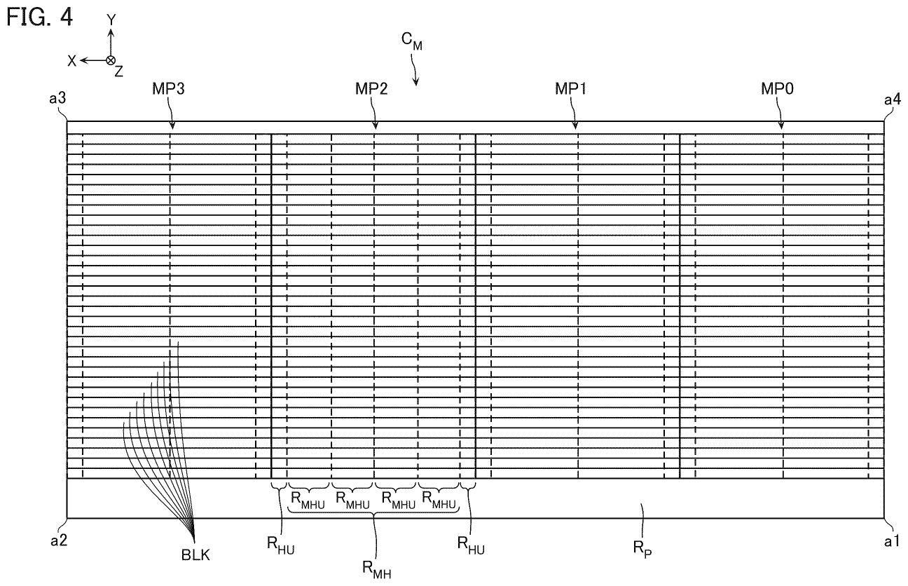

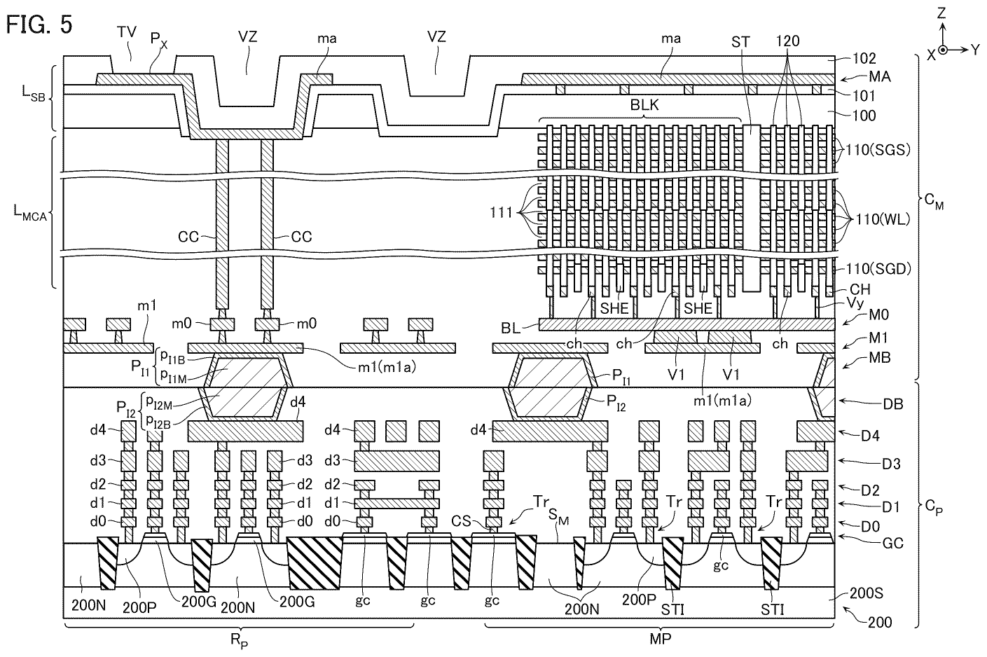

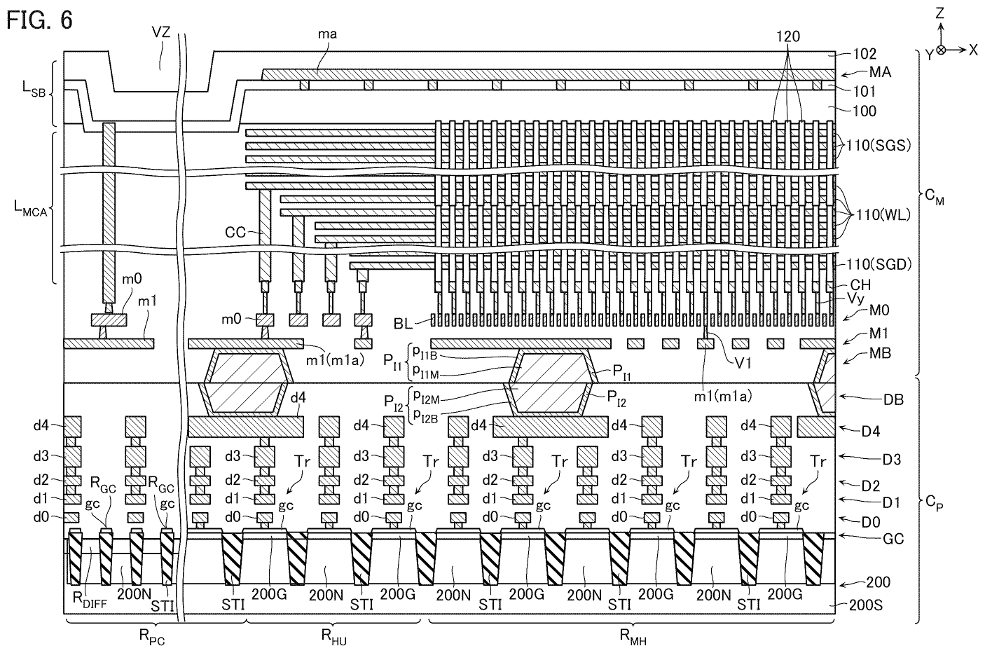

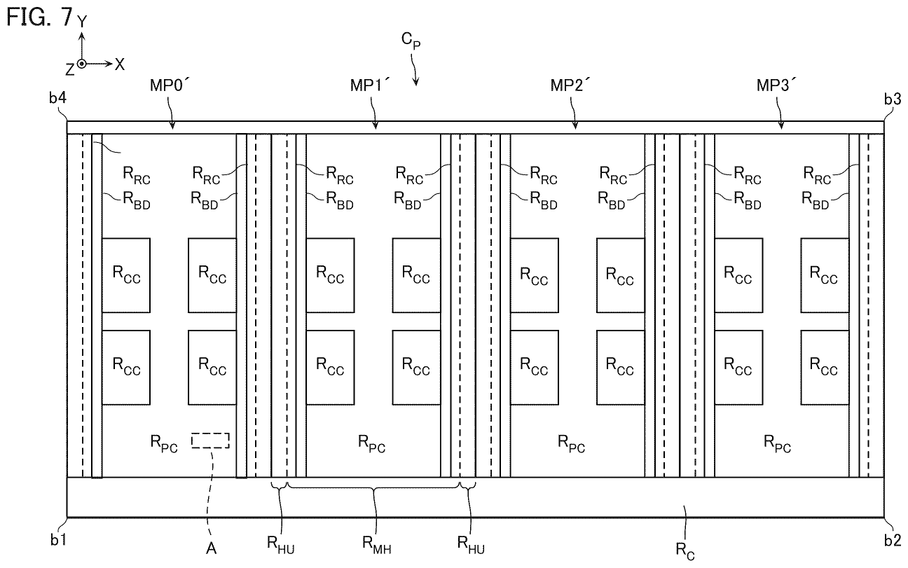

FIG. 4 is a schematic bottom view illustrating an exemplary configuration of the chip C_{M}. In FIG. 4, a configuration of a part of the bonding electrodes P_{I1} and the like is omitted. FIG. 5 and FIG. 6 are schematic cross-sectional views illustrating configurations of parts of the memory die MD. FIG. 7 is a schematic plan view illustrating an exemplary configuration of the chip C_{P}. In FIG. 7, a configuration of a part of the bonding electrodes P_{I2} and the like is omitted.

### [Structure of Chip C_{M}]

In the example of FIG. 4, the chip C_{M} includes four memory planes MP0 to MP3 arranged in the X-direction. The four memory planes MP0 to MP3 may each be referred simply to as a memory plane MP. These four memory planes MP0 to MP3 each include the plurality of memory blocks BLK arranged in the Y-direction. In the example of FIG. 4, these four memory planes MP0 to MP3 each include hook-up regions Rau disposed at both end portions in the X-direction and a memory hole region R_{MH} (memory region) disposed between the hook-up regions R_{HU}. In the example of FIG. 4, the memory hole region R_{MH} is divided into four regions R_{MHU} in the X-direction. These four regions R_{MHU} have widths in the X-direction that may all be the same or are not necessarily the same. The chip C_{M} includes a peripheral region R_{P} disposed on one end side in the Y-direction with respect to the four memory planes MP0 to MP3.

In the illustrated example, the hook-up regions R_{HU} are disposed at both end portions in the X-direction of the memory plane MP. However, such a configuration is merely an example, and a specific configuration is adjustable as appropriate. For example, the hook-up region R_{HU} may be disposed at one end portion in the X-direction, not at both the end portions in the X-direction of the memory plane. The hook-up region R_{HU} may be disposed at a center position in the X-direction of the memory plane MP or a position close to the center.

For example, as illustrated in FIG. 5, the chip C_{M} includes a substrate layer L_{SB}, a memory cell array layer L_{MCA} disposed below the substrate layer L_{SB}, a via-contact electrode layer CH disposed below the memory cell array layer L_{MCA}, a plurality of wiring layers M0, M1 disposed below the via-contact electrode layers CH, and the chip bonding electrode layer MB disposed below the wiring layers M0, M1.

[Structure of Substrate Layer L_{SB} in Chip C_{M}]

For example, as illustrated in FIG. 5, the substrate layer L_{SB} includes a conductive layer 100 disposed on an upper surface of the memory cell array layer L_{MCA}, an insulating layer 101 disposed on an upper surface of the conductive layer 100, a back surface wiring layer MA disposed on an upper surface of the insulating layer 101, and an insulating layer 102 disposed on an upper surface of the back surface wiring layer MA.

The conductive layer 100 may include, for example, a semiconductor layer of, for example, silicon (Si) into which N-type impurities, such as phosphorus (P), or P-type impurities, such as boron (B), are implanted, may include a metal, such as tungsten (W), or may include silicide, such as tungsten silicide (WSi).

The conductive layer 100 functions as a part of the source line SL (FIG. 2). Four conductive layers 100 are disposed corresponding to the four memory planes MP0 to MP3 (FIG. 4). Regions VZ that do not include the conductive layers 100 are disposed at end portions in the X-direction and the Y-direction of the memory plane MP.

The insulating layer 101 contains, for example, silicon oxide (SiO₂) or the like.

The back surface wiring layer MA includes a plurality of wirings ma. These plurality of wirings ma may contain, for example, aluminum (Al) or the like.

Some of the plurality of wirings ma function as a part of the source line SL (FIG. 2). Four such wirings ma are, for example, disposed corresponding to the four memory planes. These wirings ma are electrically connected to the respective conductive layers 100.

In addition, some of the plurality of wirings ma function as the external pad electrodes P_{X}. These wirings ma are disposed in the peripheral region R_{P}. These wirings ma are connected to via-contact electrodes CC in the memory cell array layers L_{MCA} in the region VZ that does not include the conductive layer 100. A part of the wirings ma is exposed to an outside of the memory die MD via an opening TV provided in the insulating layer 102.

The insulating layer 102 is, for example, a passivation layer formed of an insulating material, such as polyimide.

[Structure of Memory Cell Array Layer L_{MCA} of Chip C_{M} In Hook-Up Region R_{HU}]

As illustrated in FIG. 6, the plurality of via-contact electrodes CC are disposed in the hook-up region R_{HU}. These plurality of via-contact electrodes CC each extend in the Z-direction and are connected to conductive layers 110 (WL, SGD, SGS) at upper ends of these plurality of via-contact electrodes CC.

[Structure of Memory Cell Array Layer L_{MCA} of Chip C_{M} in Peripheral Region R_{P}]

For example, as illustrated in FIG. 5, the plurality of via-contact electrodes CC are disposed corresponding to the external pad electrode P_{X} in the peripheral region R_{P}. These plurality of via-contact electrodes CC are connected to the external pad electrode P_{X} at upper ends of these plurality of via-contact electrodes CC.

### [Structure of Via-Contact Electrode Layer CH]

The plurality of via-contact electrodes ch included in the via-contact electrode layer CH are, for example, electrically connected to at least one of configurations in the memory cell array layer L_{MCA} and configurations in the chip C_{P}.

The via-contact electrode layer CH includes the plurality of via-contact electrodes ch as the plurality of wirings. These plurality of via-contact electrodes ch may include, for example, a stacked film of a barrier conductive film of titanium nitride (TiN) or the like and a metal film of tungsten (W) or the like. The via-contact electrodes ch are disposed corresponding to a plurality of semiconductor layers 120, and are connected to lower ends of the plurality of semiconductor layers 120.

### [Structure of Wiring Layers M0, M1 of Chip C_{M}]

A plurality of wirings included in the wiring layers M0, M1 are, for example, electrically connected to at least one of the configurations in the memory cell array layers L_{MCA} and the configurations in the chip C_{P}.

The wiring layer M0 includes a plurality of wirings m0. These plurality of wirings m0 may include, for example, a stacked film of a barrier conductive film, such as titanium nitride (TiN), tantalum nitride (TaN), and a stacked film of tantalum nitride (TaN) and tantalum (Ta); and a metal film, such as copper (Cu). Note that some of the plurality of wirings m0 function as the bit lines BL. The bit lines BL are arranged in, for example, the X-direction and extend in the Y-direction.

For example, as illustrated in FIG. 5, the wiring layer M1 includes the plurality of wirings ml. These plurality of wirings ml may include, for example, a stacked film of a barrier conductive film, such as titanium nitride (TiN), and a metal film, such as tungsten (W).

### [Structure of Chip Bonding Electrode Layer MB]

The plurality of wirings included in the chip bonding electrode layer MB are, for example, electrically connected to at least one of the configurations in the memory cell array layer L_{MCA} and the configurations in the chip C_{P}.

The chip bonding electrode layer MB includes the plurality of bonding electrodes P_{I1} (bonding pads). These plurality of bonding electrodes P_{I1} may include, for example, a stacked film of a barrier conductive film p_{I1B}, such as titanium nitride (TiN), tantalum nitride (TaN), and a stacked film of tantalum nitride (TaN) and tantalum (Ta); and a metal film prim, such as copper (Cu).

### [Structure of Chip C_{P}]

For example, as illustrated in FIG. 7, the chip C_{P} includes regions MP0′ to MP3′ arranged in the X-direction and overlapping the four memory planes MP0 to MP3. Row control circuit regions R_{RC} are disposed at both end portions in the X-direction of each of these four regions MP0′ to MP3′. Additionally, between these two row control circuits regions R_{RC}, two block decoder regions R_{BD} arranged in the X-direction are disposed. Additionally, between these two block decoder regions R_{BD}, a peripheral circuit region R_{PC} is disposed. The peripheral circuit region R_{PC} is provided with four column control circuit regions R_{CC} arranged in the X-direction and the Y-direction. Although the illustration is omitted, a circuit is also disposed in another region in the peripheral circuit region R_{PC}. A circuit region R_{C} is disposed in a region of the chip C_{P} opposed to the peripheral region R_{P} (FIG. 4) of the chip C_{M}.

The chip C_{P} includes, for example, as illustrated in FIG. 5, a semiconductor substrate 200, an electrode layer GC disposed above the semiconductor substrate 200, wiring layers D0, D1, D2, D3, D4 disposed above the electrode layer GC, and a chip bonding electrode layer DB disposed above the wiring layers D0, D1, D2, D3, D4.

### [Structure of Semiconductor Substrate 200 in Chip C_{P}]

The semiconductor substrate 200, for example, contains P-type silicon (Si) containing P-type impurities, such as boron (B). The semiconductor substrate 200 has a main surface S_{M} on a side of the electrode layer GC and the wiring layers D0, D1, D2, D3, D4. On a surface on a side of the main surface S_{M} of the semiconductor substrate 200, for example, an N-type diffusion layer 200N containing N-type impurities, such as phosphorus (P), a P-type diffusion layer 200P containing P-type impurities, such as boron (B), a semiconductor substrate region 200S in which the N-type diffusion layer 200N or the P-type diffusion layer 200P is not disposed, and an insulating layer STI are disposed. A part of the P-type diffusion layer 200P is disposed in the semiconductor substrate region 200S, and a part of the P-type diffusion layer 200P is disposed in the N-type diffusion layer 200N. The respective N-type diffusion layers 200N, the P-type diffusion layers 200P disposed in the N-type diffusion layer 200N and the semiconductor substrate region 200S, and the semiconductor substrate region 200S function as parts of a plurality of transistors Tr, a plurality of capacitors, and the like constituting the peripheral circuit PC. Note that a part of the plurality of transistors Tr functions as the word line switches WLSW and the select gate line switches SGSW.

### [Structure of Electrode Layer GC in Chip C_{P}]

The electrode layer GC is disposed on an upper surface of the semiconductor substrate 200 via an insulating layer 200G. The electrode layer GC includes a plurality of electrodes gc opposed to the surface of the semiconductor substrate 200. Each of the plurality of electrodes gc included in each of the regions of the semiconductor substrate 200 and the electrode layer GC is connected to the via-contact electrode CS.

The respective N-type diffusion layers 200N, P-type diffusion layers 200P disposed in the N-type diffusion layer 200N and the semiconductor substrate region 200S, and the semiconductor substrate region 200S of the semiconductor substrate 200 function as channel regions of the plurality of transistors Tr, one electrodes of the plurality of capacitors, and the like constituting the peripheral circuit PC. As illustrated in FIG. 6, a part of the P-type diffusion layer 200P of the semiconductor substrate 200 functions as the diffusion resistor R_{DIFF}, which is the first resistor element.

The respective plurality of electrodes gc included in the electrode layer GC function as gate electrodes of the plurality of transistors Tr, the other electrodes of the plurality of capacitors, and the like constituting the peripheral circuit PC. As illustrated in FIG. 6, a part of the plurality of electrodes gc included in the electrode layer GC functions as the GC resistor R_{GC}, which is the second resistor element.

The via-contact electrode CS extends in the Z-direction and has a lower end connected to the semiconductor substrate 200 or an upper surface of the electrode gc. The via-contact electrode CS may include, for example, a stacked film of a barrier conductive film, such as titanium nitride (TiN), and a metal film, such as tungsten (W).

### [Structure of Wiring Layers D0, D1, D2, D3, D4 of Chip C_{P}]

For example, as illustrated in FIG. 7, the plurality of connecting portions and the plurality of wirings included in the wiring layers D0, D1, D2, D3, D4 are, for example, electrically connected to at least one of the configurations in the memory cell array layer L_{MCA} and the configurations in the chip C_{P}.

The wiring layers D0, D1, D2 includes a plurality of connecting portions d0, d1, d2, respectively, and a plurality of wirings. These plurality of connecting portions d0, d1, d2 and the plurality of wirings may include, for example, a stacked film of a barrier conductive film, such as titanium nitride (TiN), and a metal film, such as tungsten (W).

The wiring layers D3, D4 include a plurality of connecting portions d3, d4, respectively, and a plurality of wirings. These plurality of connecting portions d3, d4 and plurality of wirings may include, for example, a stacked film of a barrier conductive film, such as titanium nitride (TiN), tantalum nitride (TaN), and a stacked film of tantalum nitride (TaN) and tantalum (Ta); and a metal film, such as copper (Cu).

### [Structure of Chip Bonding Electrode Layer DB]

The plurality of wirings included in the chip bonding electrode layer DB are, for example, electrically connected to at least one of the configurations in the memory cell array layer L_{MCA} and the configurations in the chip C_{P}.

The chip bonding electrode layer DB includes the plurality of bonding electrodes P_{I2}. These plurality of bonding electrodes P_{I2} may include, for example, a stacked film of a barrier conductive film P_{I2B}, such as titanium nitride (TiN), tantalum nitride (TaN), and a stacked film of tantalum nitride (TaN) and tantalum (Ta); and a metal film p_{I2M}, such as copper (Cu).

When the metal films p_{I1M}, p_{I2M}, such as copper (Cu), are used for the bonding electrode P_{I1} and the bonding electrode P_{I2}, the metal film p_{I1M} and the metal film p_{I2M} are integrated, and confirmation of the mutual boundary is difficult. However, the bonding structure can be confirmed by distortion of the shape of bonding the bonding electrode P_{I1} and the bonding electrode P_{I2} due to a positional displacement of the bonding and the positional displacement (generation of discontinuous portions in side surfaces) of the barrier conductive films p_{I1B}, P_{I2B}. Additionally, when the bonding electrode P_{I1} and the bonding electrode P_{I2} are formed by damascene method, the respective side surfaces have a tapered shape. In view of this, the shape of the cross-sectional surface along the Z-direction in the part where the bonding electrode P_{I1} and the bonding electrode P_{I2} are bonded has a non-rectangular shape with non-linear side walls. Additionally, when the bonding electrode P_{I1} and the bonding electrode P_{I2} are bonded, a structure of covering the bottom surface, the side surface, and an upper surface of each Cu forming them by a barrier metal is formed. In contrast to this, in a wiring layer using general Cu, an insulating layer (for example, SiN or SiCN) having an oxidation reduction function of Cu is disposed on the upper surface of Cu, and a barrier metal is not disposed. In view of this, even when the positional displacement of the bonding does not occur, distinction with a general wiring layer is possible.

[Patterns of Diffusion Resistor R_{DIFF} and GC Resistor R_{GC}]

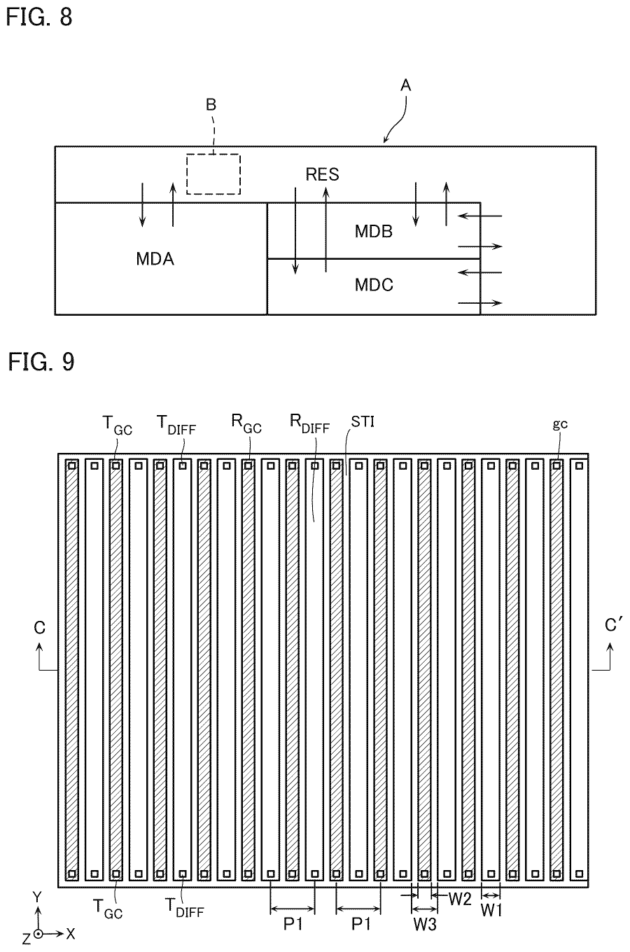

FIG. 8 is a plan view illustrating an enlarged circuit region A in the peripheral circuit region R_{PC} illustrated in FIG. 7. Note that this circuit region A may be disposed in another region, such as the peripheral region R_{P}.

The circuit region A includes three circuit modules MDA, MDB, MDC, and a resistor element region RES disposed in their periphery. a plurality of diffusion resistors R_{DIFF} as a plurality of first resistor elements and a plurality of GC resistors R_{GC} as a plurality of second resistor elements are formed in the resistor element region RES. The diffusion resistors R_{DIFF} and the GC resistors R_{GC} are connected to three circuit modules MDA, MDB, MDC as a part of a circuit element. Note that the number and the arrangement of the circuit modules are not limited to that exemplarily illustrated.

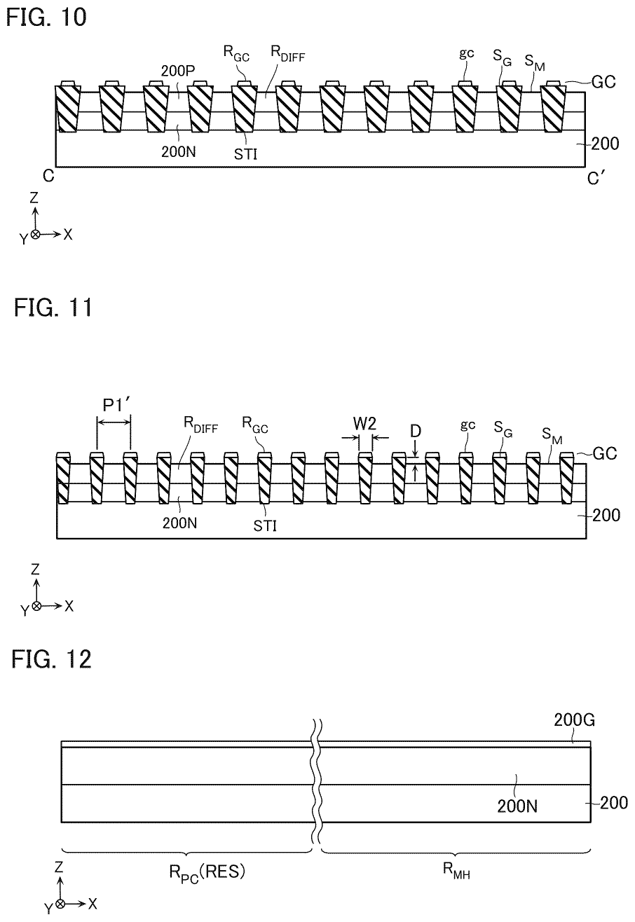

FIG. 9 and FIG. 10 are drawings illustrating patterns of the diffusion resistors R_{DIFF} and the GC resistors R_{GC} according to the first embodiment. FIG. 9 is an enlarged plan view of the circuit region B in the resistor element region RES in FIG. 8. FIG. 10 is a cross-sectional view taken along the line C-C′ in FIG. 9, and viewed from the arrow direction.

The resistor element region RES in the embodiment includes the plurality of diffusion resistors R_{DIFF} disposed at the main surface S_{M} side of the semiconductor substrate 200 and the plurality of CG resistors R_{GC} disposed in the electrode layer GC arranged on a side opposed to the main surface S_{M} of the semiconductor substrate 200. The plurality of diffusion resistors R_{DIFF} are formed of the plurality of P-type diffusion layers 200P formed in the N-type diffusion layer 200N (N well) in this example. The plurality of diffusion resistors R_{DIFF} each extend in the Y-direction parallel to the main surface S_{M} of the semiconductor substrate 200, and are arranged at a predetermined pitch P1 in the X-direction intersecting with the Y-direction in parallel to the main surface S_{M} of the semiconductor substrate 200. Each of the diffusion resistors R_{DIFF} has first connecting terminal portions T_{DIFF} at end portion sides in the Y-direction, such as at both ends.

The insulating layer STI is disposed at the main surface S_{M} side of the semiconductor substrate 200 between the plurality of diffusion resistors R_{DIFF}. The insulating layer STI surrounds side surfaces along the X-direction and the Y-direction of each of the plurality of diffusion resistors R_{DIFF}, and mutually insulates the plurality of diffusion resistors R_{DIFF}. The insulating layer STI has a surface at a side of the electrode layer GC that functions as an electrode installation surface S_{G}. The electrode installation surface S_{G} projects to positions in contact with a lower surface of the electrode layer GC from upper surface (the main surface S_{M}) of the diffusion resistor R_{DIFF}.

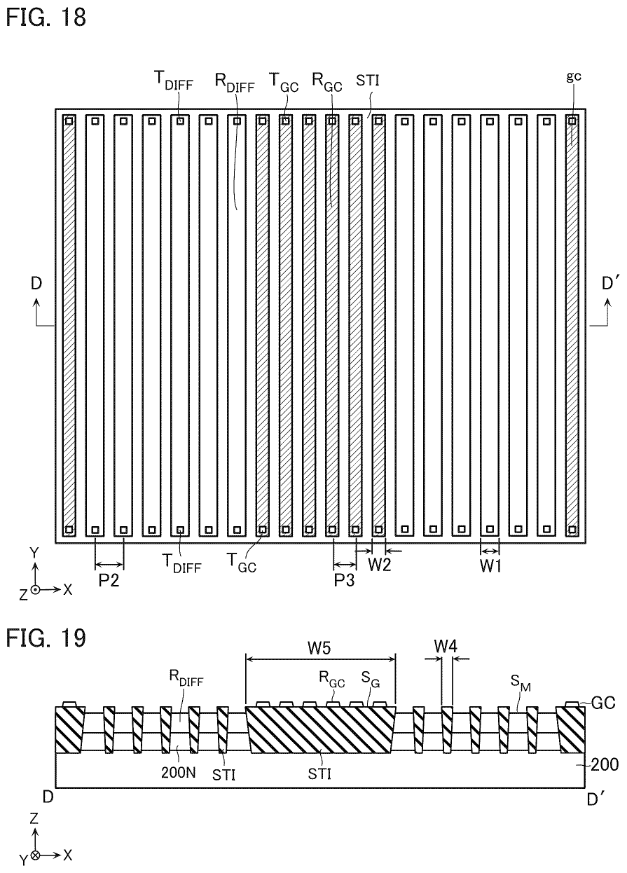

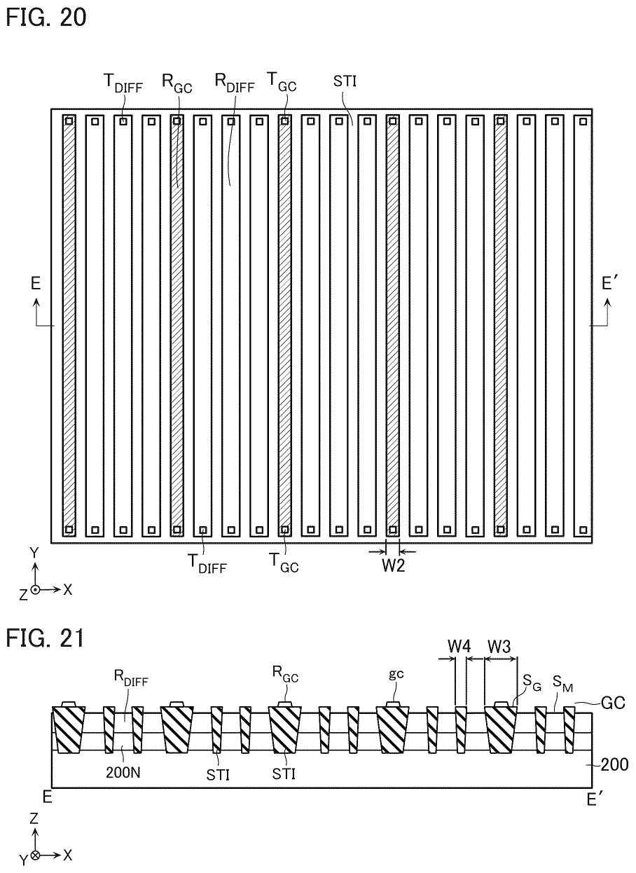

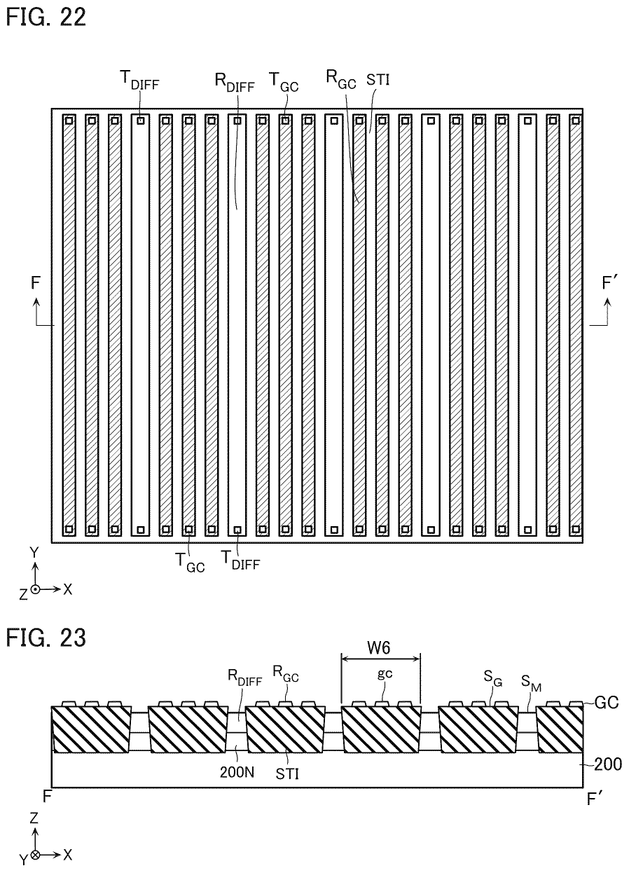

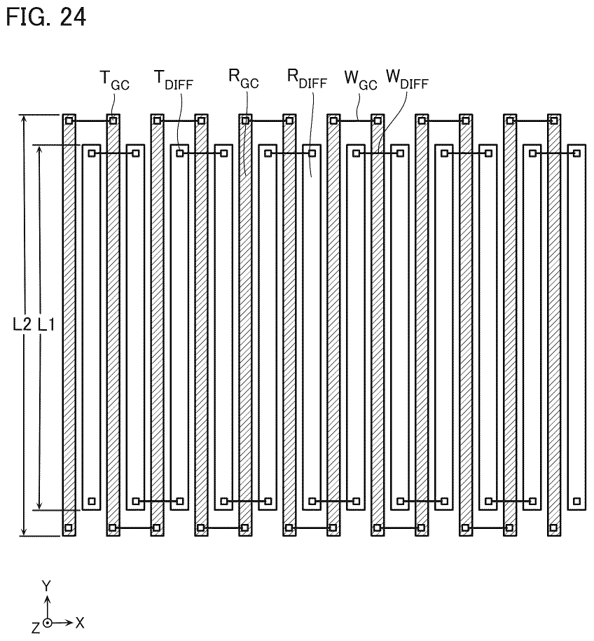

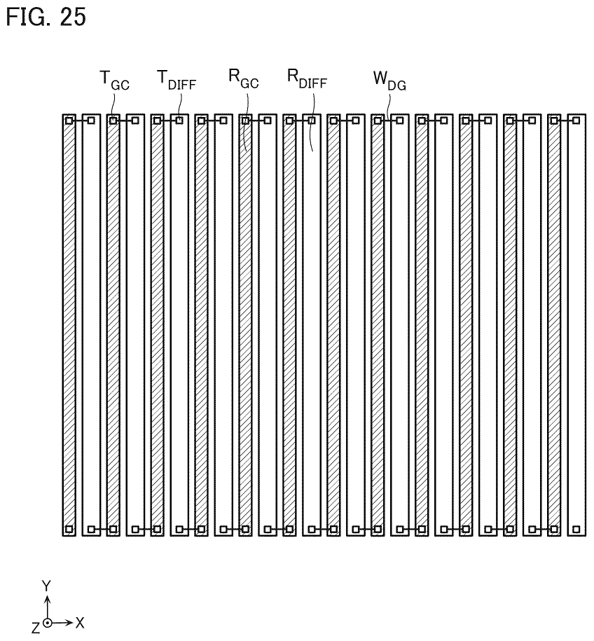

The electrode layer GC has the plurality of GC resistors R_{GC} formed of the electrodes gc on the electrode installation surface S_{G} of the insulating layer STI between the plurality of diffusion resistors R_{DIFF}. Note that FIG. 9 shows the GC resistors R_{GC} with hatching in order to distinguish the GC resistors R_{GC} from the diffusion resistors R_{DIFF}. The same applies to FIG. 18, FIG. 20, FIG. 22, FIG. 24, and FIG. 25. The plurality of GC resistors R_{GC} each extend in the Y-direction on the electrode installation surface S_{G} of the insulating layer STI, and are arranged at the predetermined pitch P1 substantially equal to the plurality of diffusion resistors R_{DIFF} in the X-direction. The GC resistors R_{GC} each have second connecting terminal portions Tec at end portion sides in the Y-direction, for example, at both ends.

In this embodiment, the plurality of diffusion resistors R_{DIFF} and the plurality of GC resistors R_{GC} are alternately arranged one by one in the X-direction.

Note that, in this embodiment, a width W1 in the X-direction of the diffusion resistor R_{DIFF} is larger than a width W2 in the X-direction of the GC resistor R_{GC}. A width W3 in the X-direction of the insulating layer STI is larger than the width W2 in the X-direction of the GC resistor R_{GC}. However, the widths W1, W2 may be substantially equal.

### Effects of the Embodiment

On the surface of the semiconductor substrate 200, it is necessary to ensure 15% to 30% or more each of a size of the region covered with the electrodes gc in a certain size (hereinafter referred to as a “GC coverage factor”) and a size of the region not covered with the electrodes gc in the above-described certain size (hereinafter referred to as an “AA coverage factor”) in order to prevent variations or the like in a flattening process. When a pattern of only the diffusion resistors R_{DIFF} is formed in the resistor element region RES, it is necessary to form a fill pattern of the electrodes gc in a periphery of the diffusion resistor R_{DIFF} to ensure a necessary GC coverage factor. Similarly, when a pattern of only the GC resistors R_{GC} is formed in the resistor element region RES, it is necessary to form a fill pattern of the region without the electrodes gc in a periphery of the GC resistor R_{GC} to ensure a necessary AA coverage factor.

In this case, an extra fill area other than the resistor elements is necessary in both cases, and thus, there is a problem of an increased cell size by the size of the extra fill area.

On the other hand, in this embodiment, the diffusion resistors R_{DIFF} and the GC resistors R_{GC} are alternately arranged one by one, and therefore, the GC coverage factor and the AA coverage factor can be satisfied at the same time without providing a fill area. In view of this, the size of the resistor element region RES can be reduced.

### Modification of First Embodiment

FIG. 11 is a cross-sectional view that illustrates a modification of the first embodiment and corresponds to FIG. 10.

In this modification, the width W2 in the X-direction of the electrode installation surface S_{G} of the insulating layer STI is substantially equal to the width W2 in the X-direction of the GC resistor R_{GC}. Also in this case, the electrode installation surface S_{G} of the insulating layer STI projects by a distance D to the electrode layer GC side with respect to the upper surface (the main surface S_{M}) of the diffusion resistor R_{DIFF}, and therefore, the GC resistor R_{GC} and the diffusion resistor R_{DIFF} can be disposed spaced from one another. In view of this, a mutual insulating property is ensured. With this modification, a pitch P1′ in the X-direction of the GC resistors R_{GC} and the diffusion resistors R_{DIFF} can be reduced smaller than the pitch P1 in the first embodiment, thus enabling a further reduced chip area.

[Method for Manufacturing Diffusion Resistor R_{DIFF} and GC Resistor R_{GC}]

FIG. 12 to FIG. 17 are cross-sectional views for describing the method for manufacturing the diffusion resistors R_{DIFF} and the GC resistors R_{GC} according to the embodiment. FIG. 12 to FIG. 17 illustrate the resistor element region RES in the peripheral circuit region R_{PC} and the other regions, for example, a region in which the transistors Tr of the memory hole region R_{MH} are formed.

Upon manufacturing the diffusion resistors R_{DIFF} and the GC resistors R_{GC}, for example, as illustrated in FIG. 12, the insulating layer 200G is formed on a surface of the semiconductor substrate 200 on which the N-type diffusion layer 200N (N well) is selectively formed in advance. This process is performed by a method such as thermal oxidation, for example.

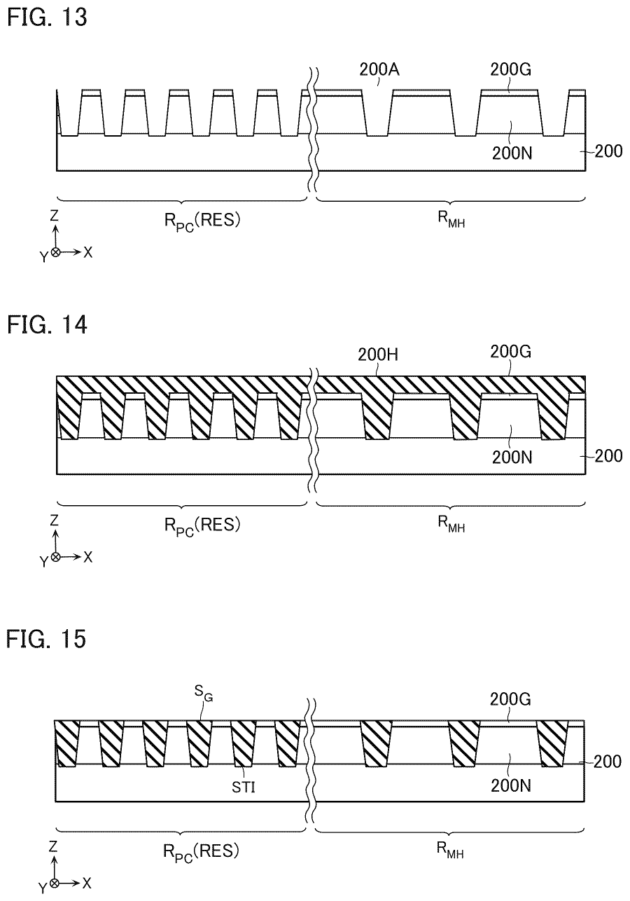

Next, for example, as illustrated in FIG. 13, openings 200A are formed at positions corresponding to the insulating layer STI described with reference to FIG. 10. The openings 200A extend in the Z-direction and the Y-direction, and extend in the X-direction at both ends in the Y-direction. The openings 200A pass through the insulating layer 200G and the N-type diffusion layer 200N in the Z-direction to divide parts of the surface of the semiconductor substrate 200. This process is performed by a method such as RIE, for example.

Next, for example, as illustrated in FIG. 14, an insulating layer 200H is formed on the semiconductor substrate 200. This process is performed by a method such as CVD, for example. Here, the openings 200A are filled with the insulating layer 200H.

Next, for example, as illustrated in FIG. 15, a part of the insulating layer 200H is removed until a surface of the insulating layer 200G is exposed to form the insulating layer STI having the electrode installation surface S_{G}. This process is performed by a method such as CMP, for example.

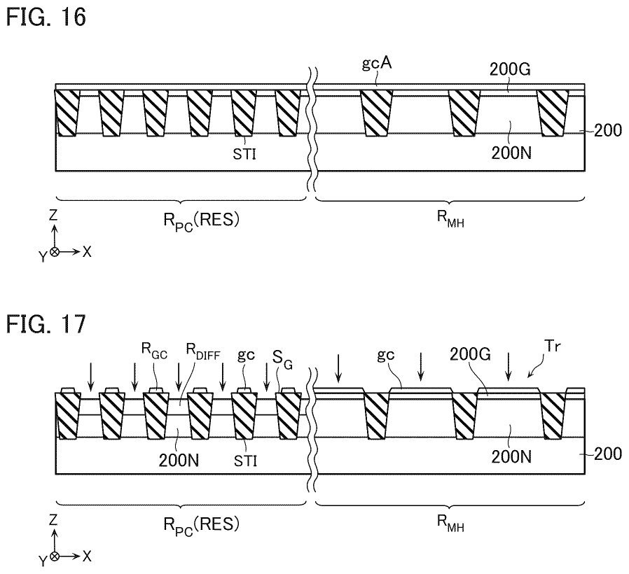

Next, for example, as illustrated in FIG. 16, a conductive layer gcA containing polysilicon, tungsten (W), or the like, or a conductive layer gcA of a two-layer structure of polysilicon and tungsten (W) is formed on the surfaces of the insulating layer STI and the insulating layer 200G. This process is performed by CVD, thermal oxidation method, sputtering, or the like, for example.

Next, for example, as illustrated in FIG. 17, parts of the conductive layer gcA are removed to expose the surfaces of the semiconductor substrate 200 to form the plurality of electrodes gc. This process is performed by a method such as RIE, for example.

This forms the GC resistors R_{GC} formed of the electrodes gc on the electrode installation surface S_{G} of the insulating layer STI in the resistor element region RES. In the region of the memory hole region R_{MH} in which the transistors Tr are formed, gates formed of the electrodes gc are formed on the insulating layers 200G.

Next, P-type impurities, such as boron (B), are implanted into a surface of the N-type diffusion layer 200N of the exposed semiconductor substrate 200. This process is performed by a method, such as ion implantation, for example.

This forms the diffusion resistors R_{DIFF} by the P-type diffusion layer on the N-type diffusion layer 200N surrounded by the insulating layer STI in the resistor element region RES. In the region of the memory hole region R_{MH} in which the transistors Tr are formed, the P-type diffusion layers that function as the drain and the source are formed on both sides in the Y-direction of the electrodes gc functioning as the gates.

### Second Embodiment

FIG. 18 and FIG. 19 are drawings illustrating patterns of the diffusion resistors R_{DIFF} and the GC resistors R_{GC} according to a second embodiment. FIG. 18 is an enlarged plan view of a region corresponding to the region illustrated in FIG. 9. FIG. 19 is a cross-sectional view taken along the line D-D′ in FIG. 18 and viewed from the arrow direction.

In this embodiment, the diffusion resistors R_{DIFF} and the GC resistors R_{GC} are alternately arranged in units of a plurality (in this example, units of six) in the X-direction. A width W4 in the X-direction of the insulating layer STI between the diffusion resistors R_{DIFF} adjacent in the X-direction is smaller than the width W2 in the X-direction of the GC resistor R_{GC} and is set to be the smallest width that is able to insulate between the diffusion resistors R_{DIFF}. A width W5 of the insulating layer STI on which the GC resistors R_{GC} are disposed is larger than the width W4, and is set to be a width that is able to dispose six GC resistors R_{GC}.

The diffusion resistors R_{DIFF} are arranged at a predetermined pitch P2 in the X-direction, and the GC resistors R_{GC} are arranged at a predetermined pitch P3 in the X-direction. When the width W2 in the X-direction of the GC resistor R_{GC} is smaller than the width W1 in the X-direction of the diffusion resistor R_{DIFF}, the pitch P3 is allowed to be smaller than the pitch P2 when the spaces in the X-direction of the diffusion resistors R_{DIFF} and the GC resistors R_{GC} have a constant width. Note that the pitch P2 of the diffusion resistors R_{DIFF} and the pitch P3 of the GC resistors R_{GC} may be the same. Other configurations are similar to that of the first embodiment, and therefore, the detailed description of the overlapping part is omitted.

In this embodiment, in addition to the effects similar to those of the first embodiment, the plurality of diffusion resistors R_{DIFF} and the plurality of GC resistors R_{GC} are alternately arranged in units of the plurality, and therefore, a connecting pattern can be simplified depending on an aspect of a connecting wiring pattern to a circuit unit to be connected. Note that the number of the plurality of diffusion resistors R_{DIFF} and the plurality of GC resistors R_{GC} that constitute the unit of the plurality is not limited to six, and is allowed to be conveniently determined within a range satisfying the AA coverage factor and the GC coverage factor.

### Third Embodiment

FIG. 20 and FIG. 21 are drawings illustrating patterns of the diffusion resistors R_{DIFF} and the GC resistors R_{GC} according to a third embodiment. FIG. 20 is an enlarged plan view of a region corresponding to the region illustrated in FIG. 9. FIG. 21 is a cross-sectional view taken along the line E-E′ in FIG. 20 and viewed from the arrow direction.

In this embodiment, three diffusion resistors R_{DIFF} and one GC resistor R_{GC} are alternately arranged in the X-direction. The width W4 in the X-direction of the insulating layer STI between the diffusion resistors R_{DIFF} adjacent in the X-direction is smaller than the width W2 in the X-direction of the GC resistor R_{GC} and is set to be the minimum width that is able to insulate between the diffusion resistors R_{DIFF}. A width W3 of the insulating layer STI on which the GC resistor R_{GC} is arranged is larger than the width W4 and is set to be a width in which one GC resistor R_{GC} is arrangeable. Other configurations are similar to that of the first embodiment, and therefore, the detailed description of the overlapping part is omitted.

As in this embodiment, the diffusion resistors R_{DIFF} and the GC resistors R_{GC} in the different numbers may be alternately arranged. In this embodiment, it is effective as a pattern for the case where the diffusion resistors R_{DIFF} are used more than the GC resistors R_{GC}.

Also in this case, since there is no necessity of providing a fill area, the size of the resistor element region RES can be reduced.

### Fourth Embodiment

FIG. 22 and FIG. 23 are drawings illustrating patterns of the diffusion resistors R_{DIFF} and the GC resistors R_{GC} according to a fourth embodiment. FIG. 22 is an enlarged plan view of a region corresponding to the region illustrated in FIG. 9. FIG. 23 is a cross-sectional view taken along the line F-F′ in FIG. 22 and viewed from the arrow direction.

In this embodiment, one diffusion resistor R_{DIFF} and three GC resistors R_{GC} are alternately arranged in the X-direction. A width W6 of the insulating layer STI on which the GC resistors R_{GC} are disposed is set to be a width in which three GC resistors R_{GC} are arrangeable. Other configurations are similar to that of the first embodiment, and therefore, the detailed description of the overlapping part is omitted.

As in this embodiment, the diffusion resistors R_{DIFF} and the GC resistors R_{GC} in the different numbers may be alternately arranged. In this embodiment, it is effective as a pattern for the case where the GC resistors R_{GC} are used more than the diffusion resistors R_{DIFF}.

Also in this case, since there is no necessity of providing a fill area, the size of the resistor element region RES can be reduced.

### Fifth Embodiment

FIG. 24 is a drawing illustrating a pattern of the diffusion resistors R_{DIFF} and the GC resistors R_{GC} according to a fifth embodiment. FIG. 24 is an enlarged plan view of a region corresponding to the region illustrated in FIG. 9.

In this embodiment, the plurality of diffusion resistors R_{DIFF} and the plurality of GC resistors R_{GC} are alternately arranged one by one in the X-direction. A length L1 in the Y-direction of the diffusion resistor R_{DIFF} is shorter than a length L2 in the Y-direction of the GC resistor R_{GC}. The plurality of diffusion resistors R_{DIFF} are connected in series via wirings W_{DIFF} extending in the X-direction. Odd-numbered first connecting terminal portions T_{DIFF} arranged at one end of the diffusion resistors R_{DIFF} in the Y-direction are connected to even-numbered first connecting terminal portions T_{DIFF} adjacent to one side of the odd-numbered first connecting terminal portions T_{DIFF} in the X-direction, arranged at one end of the diffusion resistors R_{DIFF} in the Y-direction, via the wirings W_{DIFF} arranged at one end of the diffusion resistors R_{DIFF} in the Y-direction. Even-numbered first connecting terminal portions T_{DIFF} arranged at the other end of the diffusion resistors R_{DIFF} in the Y-direction are connected to odd-numbered first connecting terminal portions T_{DIFF} adjacent to one side of the even-numbered first connecting terminal portions T_{DIFF} in the X-direction, arranged at the other end of the diffusion resistors R_{DIFF} in the Y-direction, via the wirings W_{DIFF} arranged at the other end of the diffusion resistors R_{DIFF} in the Y-direction. The plurality of GC resistors R_{GC} are connected in series via wirings W_{GC} extending in the X-direction. Odd-numbered second connecting terminal portions T_{GC} arranged at one end of the GC resistor R_{GC} in the Y-direction are connected to even-numbered second connecting terminal portions T_{GC} adjacent to one side of the odd-numbered second connecting terminal portions Tec in the X-direction, arranged at one end of the GC resistor R_{GC} in the Y-direction, via the wirings W_{GC} arranged at one end of the GC resistor R_{GC} in the Y-direction. Even-numbered second connecting terminal portions T_{GC} arranged at the other end of the GC resistor R_{GC} in the Y-direction are connected to odd-numbered second connecting terminal portions Tec adjacent to one side of the even-numbered second connecting terminal portions T_{GC} in the X-direction, arranged at the other end of the GC resistor R_{GC} in the Y-direction, via the wirings W_{GC} arranged at the other end of the GC resistor R_{GC} in the Y-direction. Other configurations are similar to that of the first embodiment, and therefore, the detailed description of the overlapping part is omitted.

As in this embodiment, the diffusion resistors R_{DIFF} and the GC resistors R_{GC} are not necessarily in the same lengths. For example, the length L1 in the Y-direction of the diffusion resistor R_{DIFF} may be longer than the length L2 in the Y-direction of the GC resistor R_{GC}. Mutually connecting the diffusion resistors R_{DIFF} and the respective GC resistors R_{GC} in series enables providing resistor elements having a desired resistance value.

### Sixth Embodiment

FIG. 25 is a drawing illustrating a pattern of the diffusion resistors R_{DIFF} and the GC resistors R_{GC} according to a sixth embodiment. FIG. 25 is an enlarged plan view of a region corresponding to the region illustrated in FIG. 9.

In this embodiment, the plurality of diffusion resistors R_{DIFF} and the plurality of GC resistors R_{GC} are alternately arranged one by one in the X-direction viewing from the Z-direction. The plurality of diffusion resistors R_{DIFF} and the plurality of GC resistors R_{GC} are alternately connected one by one in series via wirings W_{DG} extending in the X-direction. The first connecting terminal portions T_{DIFF} arranged at one end of the diffusion resistors R_{DIFF} in the Y-direction are connected to second connecting terminal portions T_{GC} adjacent to one side of the first connecting terminal portions T_{DIFF} in the X-direction, arranged at one end of the GC resistors R_{GC} in the Y-direction, via the wirings W_{DG} arranged at one end of the diffusion resistors R_{DIFF} and the GC resistors R_{GC} in the Y-direction. The second connecting terminal portions Tec arranged at the other end of the GC resistors R_{DIFF} in the Y-direction are connected to first connecting terminal portions T_{DIFF} adjacent to one side of the second connecting terminal portions T_{GC} in the X-direction, arranged at the other end of the diffusion resistors R_{DIFF} in the Y-direction, via the wirings W_{DG} arranged at the other end of the diffusion resistors R_{DIFF} and the GC resistors R_{GC} in the Y-direction. Other configurations are similar to that of the first embodiment, and therefore, the detailed description of the overlapping part is omitted.

With this embodiment, alternately connecting the diffusion resistors R_{DIFF} and the GC resistors R_{GC} in series enables providing resistor elements having a desired resistance value.

### OTHER EMBODIMENTS

The semiconductor memory devices according to the first embodiment to the sixth embodiment are described above. However, the configurations described above are merely examples, and the specific configuration is adjustable as necessary.

For example, in the above-described respective embodiments, the P-type diffusion layer 200P formed within the N-type diffusion layer 200N (N well) is used as the diffusion resistor R_{DIFF}. However, the N-type diffusion layer 200N formed within the P-type diffusion layer 200P (P well) can be used as the diffusion resistor R_{DIFF}.

The diffusion resistor R_{DIFF} and the GC resistor R_{GC} described in the above-described respective embodiments may have parts thereof used as a dummy resistor not connected to any circuit.

In the above-described embodiments, the example of application to the NAND flash memory has been described. However, the techniques described in this specification are also applicable to a configuration other than the NAND flash memory, for example, a three-dimensional NOR flash memory. Additionally, the techniques described in this specification are also applicable to a semiconductor memory device other than the flash memory, for example, a three-dimensional DRAM and a semiconductor device other than the semiconductor memory device.

### OTHERS

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a semiconductor substrate having a main surface which includes a first direction and a second direction intersecting with the first direction;
an electrode layer disposed at a side to the main surface,
a plurality of first resistor elements disposed at a side of the main surface of the semiconductor substrate, extending in the first direction, arranged in the second direction, and formed of a plurality of diffusion layers having first connecting terminal portions at end portion sides in the first direction; and
an insulating layer disposed at the side of the main surface of the semiconductor substrate between the respective plurality of first resistor elements and having an electrode installation surface in contact with the electrode layer; wherein
the electrode layer includes:
a plurality of second resistor elements disposed on the electrode installation surface of the insulating layer between the plurality of first resistor elements, extending in the first direction, arranged in the second direction, and formed of a plurality of conductive layers having second connecting terminal portions at end portion sides in the first direction.

2. The semiconductor device according to claim 1, wherein
the plurality of first resistor elements and the plurality of second resistor elements are alternately arranged one by one in the second direction.

3. The semiconductor device according to claim 1, wherein
the plurality of first resistor elements and the plurality of second resistor elements are alternately arranged in units of a plurality in the second direction.

4. The semiconductor device according to claim 1, wherein
one second resistor element among the plurality of second resistor elements is arranged between a first plurality of first resistor elements which are a part of the plurality of first resistor elements and a second plurality of first resistor elements which are another part of the plurality of first resistor elements.

5. The semiconductor device according to claim 1, wherein
one first resistor element among the plurality of first resistor elements is arranged between a first plurality of second resistor elements which are a part of the plurality of second resistor elements and a second plurality of second resistor elements which are another part of the plurality of second resistor elements.

6. The semiconductor device according to claim 1, wherein
the plurality of diffusion layers are P-type diffusion layers.

7. The semiconductor device according to claim 1, wherein
the plurality of diffusion layers are N-type diffusion layers.

8. The semiconductor device according to claim 1, wherein
at least two of the plurality of first resistor elements are electrically connected in series via the first connecting terminal portions, and
at least two of the plurality of second resistor elements are electrically connected in series via the second connecting terminal portions.

9. The semiconductor device according to claim 1, wherein
at least two of the plurality of first resistor elements and at least two of the plurality of second resistor elements are alternately electrically connected in series one by one via the first connecting terminal portions and the second connecting terminal portions.

10. The semiconductor device according to claim 1, further comprising
a transistor having a gate electrode, wherein
the electrode layer further includes the gate electrode.

11. The semiconductor device according to claim 1, wherein
the electrode installation surface of the insulating layer projects to a side of the electrode layer with respect to the main surface of the semiconductor substrate.

12. The semiconductor device according to claim 11, wherein
a width in the second direction of the electrode installation surface of the insulating layer is equal to a width in the second direction of the second resistor element.

13. The semiconductor device according to claim 1, wherein
a width in the second direction of the first resistor element is greater than a width in the second direction of the second resistor element.

14. The semiconductor device according to claim 3, wherein
a pitch in the second direction of the plurality of first resistor elements is greater than a pitch in the second direction of the plurality of second resistor elements.

15. The semiconductor device according to claim 1, wherein
a length in the first direction of the first resistor element is different from a length in the first direction of the second resistor element.

16. A semiconductor device comprising:
a memory cell array layer;
a semiconductor substrate that has a main surface opposed to the memory cell array layer, the main surface extending in a first direction and a second direction intersecting with the first direction, and on which a peripheral circuit controlling the memory cell array layer is formed; and
an electrode layer disposed between the memory cell array layer and the main surface of the semiconductor substrate, wherein
the peripheral circuit has a resistor element region,
the resistor element region includes:
a plurality of first resistor elements disposed at a side of the main surface of the semiconductor substrate, extending in the first direction, arranged in the second direction, and formed of a plurality of diffusion layers having first connecting terminal portions at end portion sides in the first direction; and
an insulating layer disposed at the side of the main surface of the semiconductor substrate between the respective plurality of first resistor elements and having an electrode installation surface in contact with the electrode layer;
the electrode layer includes:
a plurality of second resistor elements disposed on the electrode installation surface of the insulating layer between the plurality of first resistor elements, extending in the first direction, arranged in the second direction, and formed of a plurality of conductive layers having second connecting terminal portions at end portion sides in the first direction.

17. The semiconductor device according to claim 16, wherein
the peripheral circuit further includes a transistor having a gate electrode, and
the electrode layer further includes the gate electrode.

18. The semiconductor device according to claim 16, wherein
the electrode installation surface of the insulating layer projects to a side of the electrode layer with respect to the main surface of the semiconductor substrate.
